(19) United States
(12) Patent Application Publication
(10) Pub. No.: US 2007/0158179 A1
(43) Pub. Date: Jul. 12, 2007

(54) Method and apparatus for improving symmetry of a layer deposited on a semiconductor substrate

(76) Inventors: Anthony Ciancio, Gilbert, AZ (US); Jeffrey A. Chan, Mesa, AZ (US)

Correspondence Address: INGRASSIA, FISHER & LORENZ, P.C., 7150 E. CAMELBACK ROAD, SUITE 325, SCOTTSDALE, AZ, 85251, US

(21) Appl. No.: 11/330,366

(22) Filed: Jan. 11, 2006

(51) Int. Cl. C23C 14/32; C23C 14/00

(52) U.S. Cl. 204/192.1; 204/298.02

(57) ABSTRACT

A method for forming a layer on a semiconductor substrate is provided. A semiconductor substrate having a central axis may be positioned a first distance from a first target and a second distance from a second target. The second target may have at least first and second portions on opposing sides of the central axis of the semiconductor substrate. The first and second targets may be exposed to a processing gas. First and second biases may be respectively applied to the first and second targets such that ions in the processing gas bombard the first and second targets and deposition particles are ejected from the first and second targets onto the semiconductor substrate.

### FIELD OF THE INVENTION

The present invention generally relates to a method and apparatus for forming a layer on a semiconductor substrate, and more particularly relates to a method and apparatus for sputtering metal onto a semiconductor substrate.

### BACKGROUND OF THE INVENTION

Integrated circuits are formed on semiconductor substrates (e.g., wafers). The wafers are then sawed into microelectronic dies (i.e., “dice”), or semiconductor chips, with each die carrying a respective integrated circuit. Each semiconductor chip is mounted to a package, or carrier substrate, which is often mounted to a motherboard.

The formation of the integrated circuits includes numerous processing steps such as the formation and etching of various layers of conductive, insulating, and semiconductor materials. One method for forming (e.g., depositing) a layer of metal on the surface of the semiconductor substrate is known as “sputtering.” Sputtering is typically performed in a processing chamber with a relatively large piece of the metal to be sputtered, such as aluminum or nickel, known as a “target,” at the top of the chamber. A semiconductor substrate is placed below the target at the bottom of the chamber, and a processing gas, such as argon, is introduced into the chamber. A bias (e.g., DC voltage) is applied to the target such that ions in the processing gas are attracted to and bombard the material of the target. As a result, small particles of the metal are ejected from the target and fall onto the semiconductor substrate to form a layer of the metal on the surface thereof.

One problem with conventional sputtering processes is that the metal particles do not fall onto the substrate in a uniform direction. That is, the metal particles that fall onto the central portion of the substrate do so in a direction that is substantially perpendicular to the upper surface of the substrate. However, the particles that fall onto the outer portions of the substrate do so at an angle. Therefore, certain portions of features on the substrate, such as trenches and lines, may be “shadowed” from the origin of the particles. As a result, the layer formed by the sputtering may not be symmetric (i.e., have a uniform thickness) over such features. Therefore, if the sputtering process is not performed for a sufficient amount of time, some of the shadowed portions may not be sufficiently covered by the layer.

Accordingly, it is desirable to provide a method and apparatus for forming a layer on a substrate with improved symmetry. Furthermore, other desirable features and characteristics of the present invention will become apparent from the subsequent detailed description and the appended claims, taken in conjunction with the accompanying drawings and the foregoing technical field and background.

### BRIEF DESCRIPTION OF THE DRAWINGS

The present invention will hereinafter be described in conjunction with the following drawings, wherein like numerals denote like elements, and

FIG. 1 is a cross-sectional side view of a semiconductor substrate undergoing a conventional deposition process;

FIG. 2 is a cross-sectional side view of a central portion of the semiconductor substrate of FIG. 1;

FIG. 3 is a cross-sectional side view of an outer portion of the semiconductor substrate of FIG. 1;

FIG. 4 is a cross-sectional schematic side view of a semiconductor substrate processing system according to one embodiment of the present invention;

FIG. 5 is a cross-sectional side view of a semiconductor substrate undergoing a deposition process within the processing system illustrated in FIG. 4;

FIG. 6 is a cross-sectional side view a central portion of the semiconductor substrate of FIG. 5; and

FIG. 7 is a cross-sectional side view of an outer portion of the semiconductor substrate of FIG. 5.

### DETAILED DESCRIPTION OF THE INVENTION

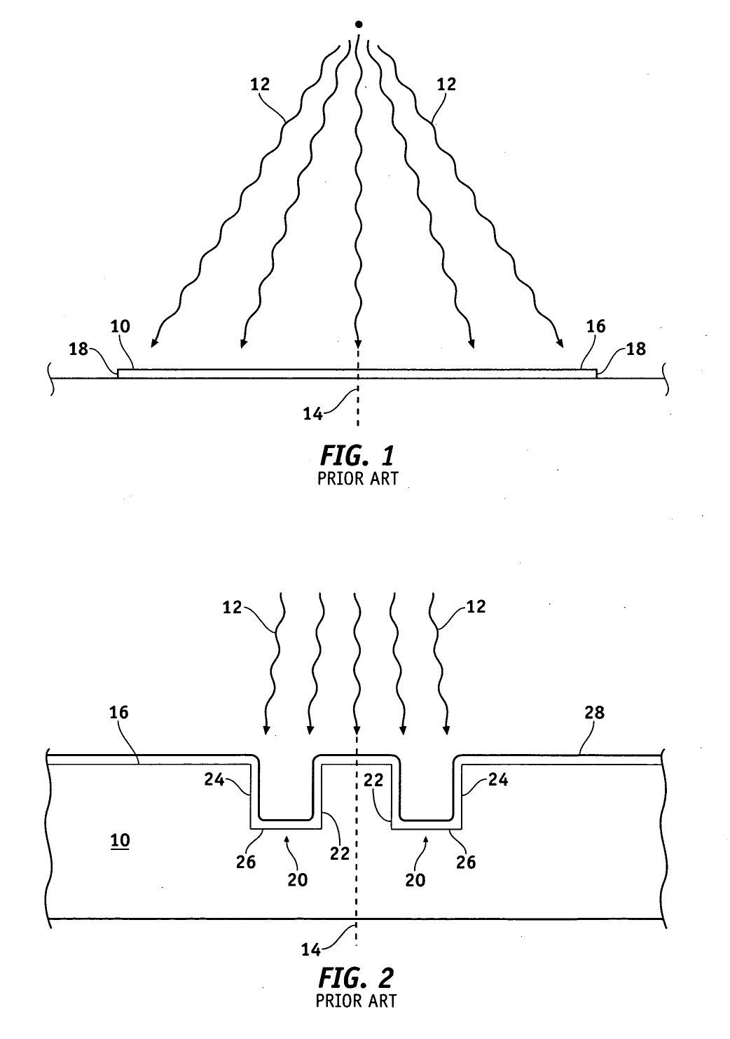

The following detailed description is merely exemplary in nature and is not intended to limit the invention or application and uses of the invention. Furthermore, there is no intention to be bound by any expressed or implied theory presented in the preceding technical field, background, brief summary, or the following detailed description. It should also be noted that FIGS. 1-7 are merely illustrative and may not be drawn to scale.

FIG. 1 illustrates a semiconductor substrate 10 undergoing a conventional sputtering process (i.e., using a single target). As shown, sputtered particles 12 fall onto the substrate 10 as if they originated from a point source and have a tendency to propagate away from a central axis 14 of the substrate 10. Therefore, the sputtered particles 12 which fall onto a central portion of the substrate 10 do so in a direction that is substantially parallel to the central axis 14, or perpendicular to an upper surface 16, of the substrate 10, while the sputtered particles 12 that fall onto outer portions of the substrate 10 do so at an angle (as measured from the central axis 14) away from the central axis 14. As indicated by the paths of the sputtered particles 12, the angle at which the sputtered particles 12 fall onto the substrate 10 gradually increases toward the edges 18 of the substrate 10.

FIG. 2 illustrates the central portion of the substrate 10 in greater detail. The substrate 10 further includes a series of trenches 20 in the upper surface 16. Each trench 20 has an inner wall 22, an outer wall 24, and a floor 26. As shown, at the central portion of the substrate 10, because the sputtered particles 12 fall onto the substrate 10 in a direction that is substantially parallel to the central axis 14, no portions of the trenches 20 are shadowed from the sputtered particles 12. Therefore, a metal layer 28 that is formed from the sputtered particles 12 covers the inner walls 22, the outer walls 24, and the floors 26 of the trenches 20 with a substantially uniform thickness.

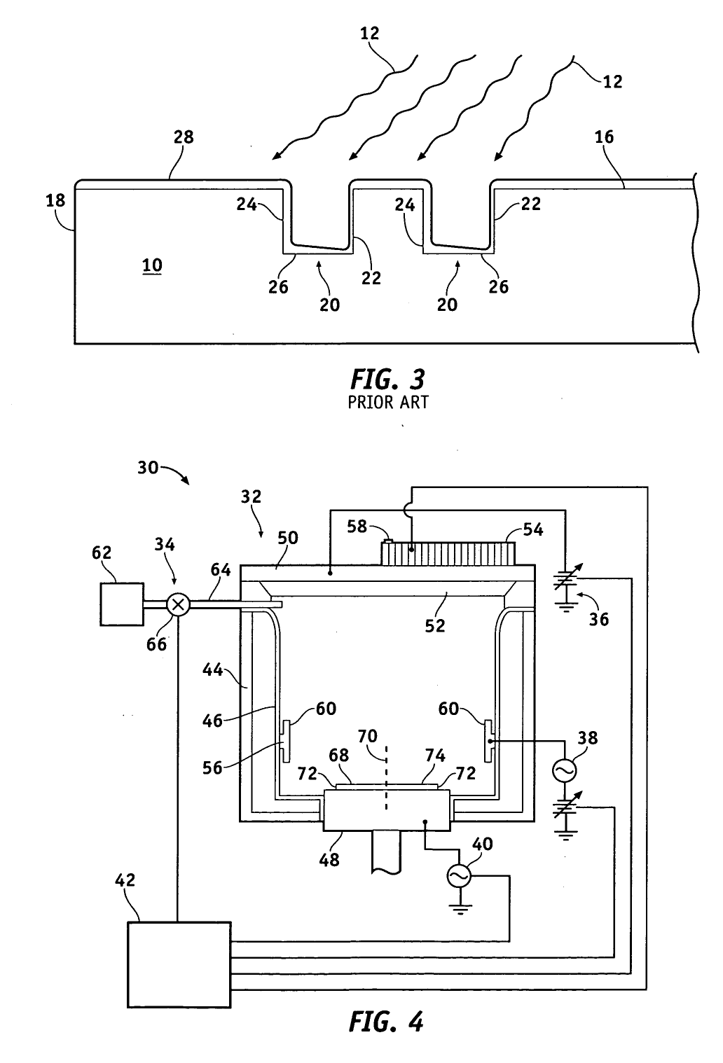

FIG. 3 illustrates an outer portion of the substrate 10 undergoing the sputtering process shown in FIG. 1. As illustrated, at the outer portion of the substrate 10 shown, the sputtered particles 12 fall onto the upper surface 16 at an angle with respect to the central axis 14, towards the edge 18 of the substrate 10 (i.e., away from the central axis 14). Therefore, the inner walls 22, as well as inner portions of the floors 26, of the trenches 20 are shadowed from the sputtered particles. As a result, the metal layer 28 does not have a uniform thickness in the trenches 20. In particular, the portions of the metal layer 28 on the inner walls 22, and inner portions of the floors 26, of the trenches 20 have a reduced thickness when compared to the portions of the metal layer 28 on non-shadowed portions, such as the outer walls 24 of the trenches.

FIG. 4 to FIG. 7 illustrate a method and system for forming (e.g., sputtering) a layer onto a semiconductor substrate with a substantially uniform thickness. The semiconductor substrate is placed on a substrate support and positioned a first distance from a first target and a second distance from a second target. The second target is shaped so that first and second portions of the second target are located on opposing sides of a central axis of the substrate. The first and second targets are exposed to a semiconductor processing gas, and first and second biases are respectively applied to the targets. The biases applied to the first and second target are sufficient to cause ions in the processing gas to bombard the first and second targets and cause sputtered particles to be ejected therefrom. The sputtered particles fall onto the substrate in various directions to form a symmetric layer on the substrate with a substantially uniform thickness.

FIG. 4 illustrates a semiconductor substrate processing system 30 according to one embodiment of the present invention. The system 30 includes a processing module 32, a processing gas supply 34, a target power supply 36, a coil power supply 38, a pedestal power supply 40, and a computer control console 42.

The processing module 32 includes a processing chamber 44 (e.g., vacuum chamber), a shield 46, a pedestal 48, and a lid 50. Although not illustrated in detail, the processing chamber 44 is cylindrically shaped and has an opening at a lower end thereof. The shield 48 is placed into the chamber 44 and includes an opening similar to that of the chamber 44. The pedestal 48 (e.g., substrate support or wafer chuck), in the depicted embodiment, is disc-shaped, positioned in the respective openings of the chamber 44 and the shield 46, and is made of an electrically conductive material. As shown, the lid 50 covers an upper end of the chamber 44 and also includes a target 52, as is commonly understood, on a lower side thereof.

Although not specifically illustrated, the target 52 is disc-shaped with a diameter of, for example, approximately 13 inches and located a height above the pedestal of, for example, between 8 and 12 inches. The target 52 is made of a sputtering material, such as a metal. Examples of metals which may be used in the target 52 include aluminum, nickel, copper, iron, tantalum, titanium, and combinations thereof. In one embodiment, the target is made of nickel iron.

The processing module 32 also includes a magnetic field generator 54 and a coil 56. The magnetic field generator 54 is rotatably connected to a central portion of an upper side of the lid 50 by a pin 58, and although not illustrated, includes a plurality of magnets. The coil 56 is an annularly shaped ring of material connected to an inner wall of the shield 46. The coil 56 is located a height above the pedestal 48 of, for example, between 2 and 3 inches and has an opening therethrough with an inner diameter, as measured from opposing inner surfaces 60 thereof, that is greater than a diameter of the pedestal 48. The coil 56 is, in one embodiment, made of the same material as the target 52.

With continued reference to FIG. 4, the processing gas supply 34 includes a processing gas container 62, a processing gas delivery tube 64, and a valve 66. The processing gas container 62 includes a processing gas, such as nitrogen, argon, krypton, or xenon. The processing gas delivery tube 64 interconnects the processing gas delivery container 62 and an interior of the processing module 32 and includes a passageway therethrough such that the processing gas container 62 and the interior of the processing module 32 are in fluid communication. The valve 66 is connected to the processing gas delivery tube 64 between the processing gas container 62 and the processing module 32.

The target power supply 36 includes a direct current (DC) power supply and is electrically connected to the target 52. The coil power supply 38 includes a radio frequency (RF) and a DC power supply and is electrically connected to the coil 56. The pedestal power supply 40 also includes a RF power supply and is electrically connected to the pedestal 48.

The computer control console 42 may be in the form of a computer, or computing system, having a memory (i.e., computer-readable medium) for storing a set of instructions (i.e., software) and a processor connected to the memory for executing the instructions, as is commonly understood in the art. The instructions stored within the computer control console 42 may include the methods and processes for controlling the semiconductor substrate processing system 30 as described below. The computer control console 42 may also include additional power supplies for the magnetic field generator 54 and the valve 66. As shown in FIG. 4, the computer control console 42 is in operable communication with the magnetic field generator 54, the target power supply 36, the coil power supply 38, the pedestal power supply 40, and the valve 66 within the processing gas supply 34.

In use, a semiconductor substrate 68, such as a wafer with a diameter of, for example, approximately 150, 200, or 300 mm (i.e., 6, 8, or 12 inches), is delivered into the processing module 32 and placed on the pedestal 48. As illustrated in FIG. 4, the substrate 68 has a central axis 70, a circular outer edge 72, and an upper (i.e., device) surface 74. Although not specifically illustrated, the substrate 68 has a thickness of, for example, between 300 and 1000 microns is made of a semiconductor material, such as gallium arsenide (GaAs), gallium nitride (GaN), or silicon (Si). The substrate 68 may be, for example, a bulk semiconductor substrate or a silicon-on-insulator (SOI) substrate. Additionally, the substrate 68 may be divided into multiplies dies, or “dice,” as commonly understood in the art, with each die carrying a respective partially completed integrated circuit.

It should also be noted that in the embodiment illustrated in FIG. 4 the diameter of the substrate 68 is less than the inner diameter of the coil 56. Additionally, in the embodiment shown, when the substrate 68 is placed on the pedestal 48, the central axis 72 of the substrate 68 passes through the opening in the coil 56 so that the coil 56 is substantially symmetric about the central axis 70 and intersects the target 52.

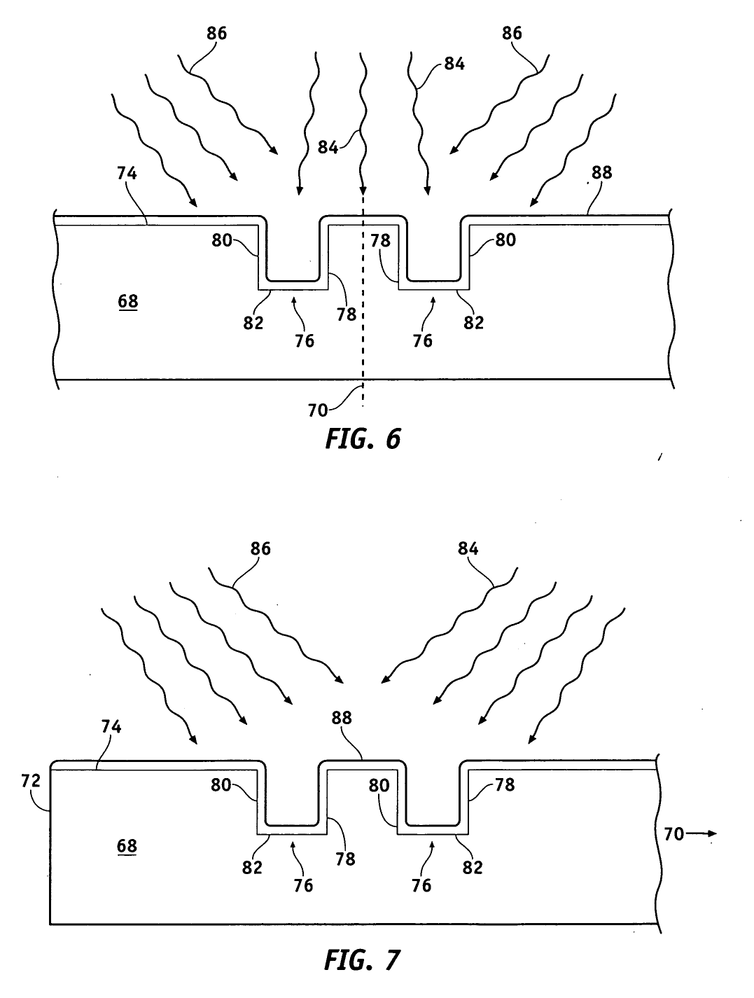

Referring now to FIGS. 6 and 7, the substrate 68 also includes a series of trenches 76 formed in the upper surface 74 thereof. Each trench 76 includes an inner wall 78, an outer wall 80, and a floor 82. As shown specifically is FIG. 6, which illustrates a central portion of the substrate 68, the inner walls 78 of the trenches 76 are the walls of the trenches that face away from the central axis 70. It should be noted that FIG. 7 illustrates an outer portion of the substrate 68. Therefore, the central axis 70 is not shown and the inner walls 78 of both trenches 76 face the same direction (i.e., away from the central axis 70).

Referring again to FIG. 4, the computer control console 42 opens the valve 66 in the processing gas supply 34 so that the processing gas within the processing gas chamber is delivered into the interior of the processing module 32. The magnetic field generator 54 rotates about the pin 58 and creates a magnetic field within the processing module, particularly below the target 52 and between the opposing inner surfaces 60 of the coil 56. The computer control console then activates the target power supply 36, the coil power supply 38, and the pedestal power supply 40. The target power supply 36 provides a DC bias (e.g., a negative DC voltage) to the target 52, for example, using at least 500 W of power from the target power supply 36. The power used from the target power supply 36 is sufficient to cause particles of the target 52 to be sputtered therefrom, as is commonly understood, and may be, for example, between 500 W (i.e., approximately 3.75 W/in² on the target 52) and 40 kW (i.e., approximately 301 W/in² on the target 52). The coil power supply 38 provides an RF and DC bias to the coil 56. The bias provided to the coil 56 has, in one embodiment, has a frequency of approximately 2 Mhz and uses between 200 and 2000 W of power from the coil power supply 38. The pedestal power supply supplies a RF bias to the pedestal with, for example, a frequency of approximately 13.56 MHz using between 0 and 600 W of power from the pedestal power supply 40.

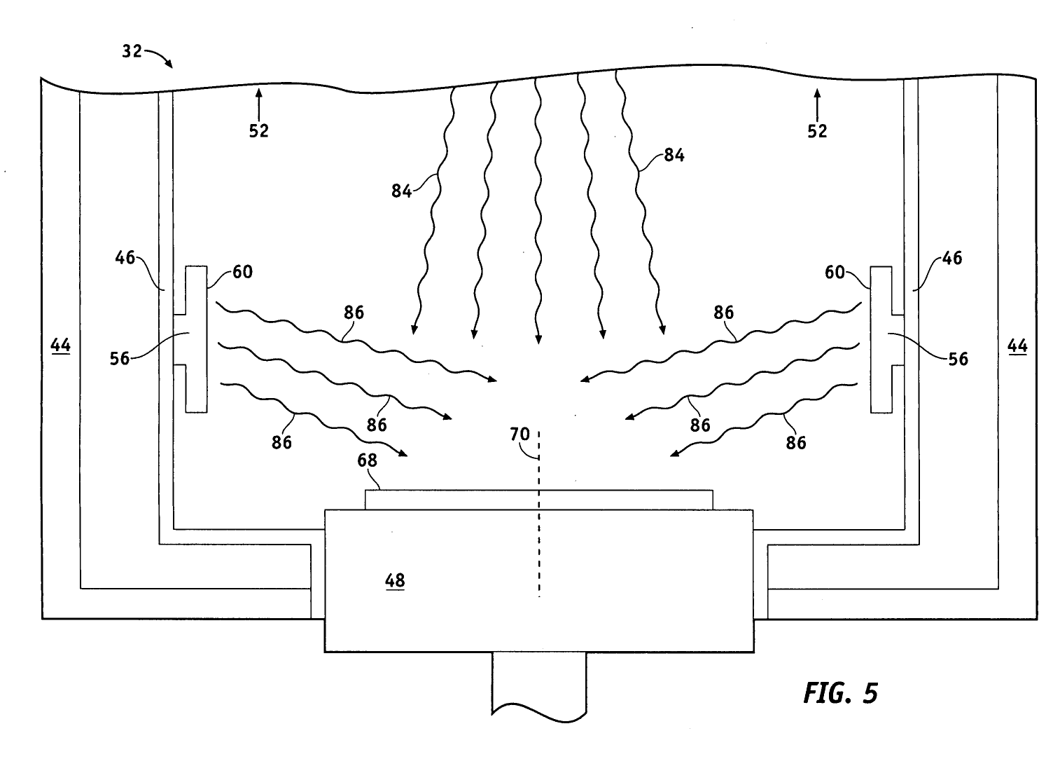

As is commonly understood in the art, the processing gas within the processing module 32 contains ionized particles (i.e., ions) which are attracted to the target 52. The ions bombard the target 52 and the coil 56 such that sputtered particles 84 (i.e., metal particles) are ejected from the material of the target 52. Because a bias is also applied to the coil 56, the ions within the processing gas are also attracted to the coil 56. Therefore, the coil 56 acts as a second target, and sputtered particles 86 are also ejected from the materials of the coil 52, as illustrated in FIG. 5. Still referring to FIG. 5, the sputtered particles 84 from the target 52 fall from the target 52 onto the substrate 68. The sputtered particles 86 from the coil 56 are ejected from the inner surfaces 60 of the coil 56 towards the central axis 70 of the substrate 68.

As specifically shown in FIG. 6, at the central portion of the substrate 68, the sputtered particles 84 from the target 52 fall onto the substrate 68 in a direction that is substantially parallel to the central axis 70 of the substrate 68. The combination of the respective sputtered particles 84 and 86 from the target 52 and the coil 56 form a metal layer 88 on the upper surface 74 of the substrate 68. As shown, the metal layer 88 is substantially symmetric (i.e., has a uniform thickness) over the upper surface 74 including the inner walls 78, outer walls 80, and floors 82 of the trenches 76.

Referring now to FIG. 7, at the outer portion of the substrate 68, the sputtered particles 84 from the target fall onto the upper surface 74 at an angle (i.e., in a direction away from the central axis 70). Thus, the inner walls 78, as well as inner portions of the floors 82, of the trenches 76 are shadowed from the sputtered particles 84 from the target 52. However, the sputtered particles 86 from the coil 56 fall onto the upper surface 74 of the substrate 68 in a direction towards the central axis 70. Therefore, the inner walls 78 and the inner portions of the floors 82 of the trenches are not shadowed from the sputtered particles 86 from the coil 56. As a result, the metal layer 88 formed from the sputtered particles 84 and 86 has a substantially uniform thickness over the outer portion of the substrate 68, as well as the inner portion illustrated in FIG. 6.

As will be appreciated by one skilled in the art, the composition of the metal layer 88 is determined by the material used in the target 52 and the coil 56. Additionally, the overall thickness of the metal layer 88 may vary depending on the time period the sputtering process is performed, as well as the various voltages and power settings of the target 52, coil 56, and pedestal 48 and the strength of the magnetic field. In one embodiment, the sputtering process is performed, for example, for between 40 and 60 seconds, and the metal layer 88 has an overall thickness of between 10 angstroms and 20 microns.

After additional processing steps and completion of the integrated circuits, the substrate 68 may be sawed into individual microelectronic dice, or semiconductor chips. The chips are then packaged and installed in various electronic or computing systems.

One advantage of the method and system described above that may occur is because the sputtered particles fall onto the substrate at various angles, particularly at the outer portions thereof, the shadowing caused by various features on the substrate may be reduced. As a result, the symmetry of the layer formed on the substrate may be improved. Another advantage that may occur is that because the symmetry of the layer formed on the substrate is improved the overall thickness of the layer may be reduced without the possibility of any portion of the substrate not being covered by the layer. A further advantage that may occur is that because multiple sputtering targets are used an increased number of sputtered particles fall onto the substrate thereby reducing the time required to form the layer.

Other embodiments of the present invention may not utilize all of the components described above. For example, the magnetic field generator may not be included. The sputtering process may be performed by applying only a DC bias to the coil, as opposed to the combination of RF and DC biases. Likewise, the sputtering process may be performed without applying any bias to the pedestal. Both of the target and the coil to not have to be used for sputtering at all times (i.e., the system may be used with only the target or coil being used as the sputtering target). The coil may be replaced with multiple, individual targets positioned around the inner wall of the shield. The various power supplies may be joined to supply power for more than one component or separated so that each component is powered by more than one power supply. Furthermore, the various voltages and power usages of the various components may vary as will be appreciated by one skilled in the art.

One embodiment includes a method for forming a layer on a semiconductor substrate. A semiconductor substrate having a central axis may be positioned a first distance from a first target and a second distance from a second target. The second target may have at least first and second portions on opposing sides of the central axis of the semiconductor substrate. The first and second targets may be exposed to a processing gas. First and second biases may be respectively applied to the first and second targets such that ions in the processing gas bombard the first and second targets and deposition particles are ejected from the first and second targets onto the semiconductor substrate.

The application of the first bias may use at least 500 W. The first distance may be greater than the second distance, and the second target may have an opening therethrough. The central axis of the semiconductor substrate may extend through the opening. The second target may be an annularly shaped coil with an inner diameter that is greater than a diameter of the semiconductor substrate. The coil may be substantially symmetric about the central axis of the semiconductor substrate. The first target may be positioned above the second target, the second target may be positioned between the first target and the semiconductor substrate, and the central axis of the semiconductor substrate may intersect the first target.

The method may also include applying a coil RF signal to the coil. The method may also include positioning the semiconductor substrate on a semiconductor substrate support, applying a third bias to the semiconductor substrate support, and applying a support RF signal to the semiconductor substrate support. The method may also include generating a magnetic field between the first and second targets. The deposition particles may form a layer on the semiconductor substrate with a thickness between 10 angstroms and 20 microns.

The first target and the second target may include at least one of nickel, iron, aluminum, copper, tantalum, and titanium, and the processing gas may include at least one of nitrogen, argon, krypton, and xenon. The second bias may be applied using between 200 W and 2000 W, the third bias may be applied using between 0 W and 600 W, the coil RF signal may have a frequency of approximately 2 MHz, and the support RF signal may have a frequency of approximately 13.56 MHz.

Another embodiment includes a method for forming a layer on a semiconductor substrate. A semiconductor substrate having a central axis may be positioned below a first metallic target and a second metallic target. The central axis of the semiconductor substrate may intersect the first metallic target. The second metallic target may be between the first metallic target and the semiconductor substrate and have at least first and second portions on opposing sides of the central axis of the semiconductor substrate and an opening through which the central axis of the semiconductor substrates extends. The first and second targets may be exposed to a processing gas. First and second biases may be respectively applied to the first and second target such that ions in the processing gas bombard the first and second targets and metallic deposition particles are ejected from the first and second metallic targets onto the semiconductor substrate.

The application of the first bias may use at least 3.75 W/in² on the first target. The second metallic target may be an annularly shaped coil with an inner diameter that is greater than a diameter of the semiconductor substrate and substantially symmetric about the central axis of the semiconductor substrate. The method may also include applying a coil RF signal to the coil. with a frequency of approximately 2 MHz.

The first target and the second target may include at least one of nickel, iron, aluminum, copper, tantalum, and titanium, and the processing gas may include at least one of nitrogen, argon, krypton, and xenon. The method may also include positioning the semiconductor substrate on a semiconductor substrate support, applying a third bias to the semiconductor substrate support and generating a magnetic field between the first metallic target and the second metallic target.

A further embodiment includes a semiconductor substrate processing apparatus. The apparatus may include a processing chamber, a semiconductor substrate support within the chamber to support a semiconductor substrate, a first target within the processing chamber and positioned above the semiconductor substrate support, a second target within the processing chamber between the first target and the semiconductor substrate support and having at least first and second portions positioned on opposing sides of a line interconnecting the first target and the semiconductor substrate support, at least one power supply connected to the first target and the second target, a controller connected to the at least one power supply to control the at least one power supply such that when a semiconductor substrate is positioned on the semiconductor substrate support and a processing gas is delivered into the processing chamber, the at least one power supply supplies a first bias to the first target and a second bias to the second target, said application of the first bias using at least 500 W, the first and second biases causing ions in the processing gas to bombard the first and second targets and deposition particles to be ejected from the first and second targets onto the semiconductor substrate.

The second target may be an annularly shaped coil having an opening therethrough with an inner diameter that is greater than a diameter of the semiconductor substrate. A central axis of the semiconductor substrate may extend through the opening when the semiconductor substrate is on the semiconductor substrate support, and the coil may be symmetric about the central axis of the semiconductor substrate. The at least one power supply may also supply a RF signal to the coil.

The apparatus may also include a magnetic field generator to generate a magnetic field between the first target and the coil. The first target and the second target may include at least one of nickel, iron, aluminum, copper, tantalum, and titanium, and the processing gas may include at least one of nitrogen, argon, krypton, and xenon.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

What is claimed is:

1. A method for forming a layer on a semiconductor substrate comprising:
positioning a semiconductor substrate having a central axis a first distance from a first target and a second distance from a second target, the second target having at least first and second portions on opposing sides of the central axis of the semiconductor substrate;
exposing the first and second targets to a semiconductor processing gas; and
applying first and second biases respectively to the first and second targets such that ions in the processing gas bombard the first and second targets and deposition particles are ejected from the first and second targets onto the semiconductor substrate.

2. The method of claim 1, wherein said application of the first bias uses at least 500 W.

3. The method of claim 1, wherein the first distance is greater than the second distance and the second target has an opening therethrough, the central axis of the semiconductor substrate extending through the opening.

4. The method of claim 3, wherein the second target is an annularly shaped coil with an inner diameter that is greater than a diameter of the semiconductor substrate.

5. The method of claim 4, wherein the first target is positioned above the second target, the second target is positioned between the first target and the semiconductor substrate, and the central axis of the semiconductor substrate intersects the first target.

6. The method of claim 1, further comprising applying a coil RF signal to the coil.

7. The method of claim 6, further comprising:
positioning the semiconductor substrate on a semiconductor substrate support;
applying a third bias to the semiconductor substrate support; and
applying a support RF signal to the semiconductor substrate support.

8. The method of claim 1, wherein the deposition particles form a layer on the semiconductor substrate, the layer having a thickness between 10 angstroms and 20 microns.

9. The method of claim 1, wherein the first target and the second target comprise at least one of nickel, iron, aluminum, copper, tantalum, and titanium and the processing gas comprises at least one of nitrogen, argon, krypton, and xenon.

10. The method of claim 7, wherein the second bias is applied using between 200 W and 2000 W, the third bias is applied using between 0 W and 600 W, the coil RF signal has a frequency of approximately 2 MHz, and the support RF signal has a frequency of approximately 13.56 MHz.

11. A method for forming a layer on a semiconductor substrate comprising:
positioning a semiconductor substrate having a central axis below a first metallic target and a second metallic target, the central axis of the semiconductor substrate intersecting the first metallic target, the second metallic target being between the first metallic target and the semiconductor substrate and having at least first and second portions on opposing sides of the central axis of the semiconductor substrate and an opening through which the central axis of the semiconductor substrates extends;
exposing the first and second targets to a semiconductor processing gas; and
applying first and second biases respectively to the first and second targets such that ions in the processing gas bombard the first and second targets and metallic deposition particles are ejected from the first and second metallic targets onto the semiconductor substrate.

12. The method of claim 11, wherein said application of the first bias uses at least 3.75 W/in² on the target.

13. The method of claim 11, wherein the second metallic target is an annularly shaped coil with an inner diameter that is greater than a diameter of the semiconductor substrate and substantially symmetric about the central axis of the semiconductor substrate.

14. The method of claim 11, wherein the first target and the second target comprise at least one of nickel, iron, aluminum, copper, tantalum, and titanium and the processing gas comprises at least one of nitrogen, argon, krypton, and xenon.

15. The method of claim 11, further comprising:
positioning the semiconductor substrate on a semiconductor substrate support;
applying a third bias to the semiconductor substrate support; and
generating a magnetic field between the first metallic target and the second metallic target.

16. A semiconductor substrate processing apparatus:
a processing chamber;
a semiconductor substrate support within the chamber to support a semiconductor substrate;
a first target within the processing chamber and positioned above the semiconductor substrate support;
a second target within the processing chamber between the first target and the semiconductor substrate support and having at least first and second portions positioned on opposing sides of a line interconnecting the first target and the semiconductor substrate support;
at least one power supply connected to the first target and the second target;
a controller connected to the at least one power supply to control the at least one power supply such that when a semiconductor substrate is positioned on the semiconductor substrate support and a semiconductor substrate processing gas is delivered into the processing chamber, the at least one power supply supplies a first bias to the first target and a second bias to the second target, said application of the first bias using at least 500 W, the first and second biases causing ions in the processing gas to bombard the first and second targets and deposition particles to be ejected from the first and second targets onto the semiconductor substrate.

17. The apparatus of claim 16, wherein the second target is an annularly shaped coil having an opening therethrough with an inner diameter that is greater than a diameter of the semiconductor substrate, a central axis of the semiconductor substrate extends through the opening when the semiconductor substrate is on the semiconductor substrate support, and the coil is symmetric about the central axis of the semiconductor substrate.

18. The apparatus of claim 17, wherein the at least one power supply further supplies a RF signal to the coil.

19. The apparatus of claim 18, further comprising a magnetic field generator to generate a magnetic field between the first target and the coil.

20. The apparatus of claim 19, wherein the first target and the second target comprise at least one of nickel, iron, aluminum, copper, tantalum, and titanium and the processing gas comprises at least one of nitrogen, argon, krypton, and xenon.
